(19) United States
(12) Patent Application Publication
(10) Pub. No.: US 2025/0221103 A1
(43) Pub. Date: Jul. 3, 2025

(54) Transparent Conductive Oxide Layer With Ohmic Contact On n-type AlInGaP for LEDs and MicroLEDs

(71) Applicant: Lumileds LLC, San Jose, CA (US)

(72) Inventors: Zhongmin Ren, Danville, CA (US); Rajiv Pathak, Milpitas, CA (US)

(73) Assignee: Lumileds LLC, San Jose, CA (US)

(21) Appl. No.: 18/397,522

(22) Filed: Dec. 27, 2023

(51) Int. Cl. H01L 33/30; H01L 25/075; H01L 33/06; H01L 33/62

(52) U.S. Cl. CPC H10H 20/824; H01L 25/0753; H10H 20/812; H10H 20/857

(57) ABSTRACT

AlInGaP LEDs and microLEDs comprise a transparent conductive oxide (TCO) layer disposed on and making Ohmic contact to an n-type AlInGaP layer. The TCO layer may be used to make electrical contact to the n-type side of the diode junction in the LED without obstructing transmission of light out of the LED through the n-type surface on which the TCO layer is disposed. The TCO layer may improve n-side current spreading. The TCO layer may be used to interconnect the n-side contacts of adjacent AlInGaP microLEDs in an array to form a shared n-side electrical contact with little or no optical cross-talk. The TCO layer may improve the reflectivity of an n-side metal contact arranged to direct light out of the LED.

### FIELD OF THE INVENTION

The invention relates generally to AlInGaP LEDs and microLEDs, and to arrays, light sources, and displays comprising AlInGaP LEDs and/or microLEDs.

### BACKGROUND

Semiconductor light emitting diodes (LEDs) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

An LED having a largest dimension of less than or equal to about 50 microns parallel to the layers forming the diode junction is referred to herein as a microLED.

In operation of an LED, a forward bias is applied across a diode junction in the LED and radiative recombination of injected electrons and holes results in the emission of light.

Direct emitting (i.e., not phosphor-converted) LEDs and microLEDs formed in the Aluminum Indium Gallium Phosphide (AlInGaP) material system are high-performance amber and red emitters that may exhibit high external quantum efficiency (EQE), emission peaks with narrow full width at half maximum (FWHM), low voltage operation, good reliability, and a wide color gamut coverage tunable by varying the composition of the light emitting active region in the device.

AlInGaP microLEDs may be used, for example, as pixel red emitters in microLED display device applications such as, for example, microLED display engines, direct-view displays, and augmented reality (AR), virtual reality (VR), and mixed reality (MR) systems. Such applications may include head-mounted (HMD) display systems. Larger AlInGaP LEDs may operate at high output power and be used, for example, in traffic lights, automotive (e.g., taillight and/or brake light) applications, and other illumination applications.

### SUMMARY

This specification discloses AlInGaP LEDs and microLEDs comprising a transparent conductive oxide layer disposed on and making Ohmic contact to an n-type AlInGaP layer. By Ohmic contact this specification means that the junction (interface) between the transparent conductive oxide layer and the n-type AlInGaP layer exhibits a linear current-voltage curve as with Ohm's law.

The transparent conductive oxide Ohmic contact layer may be formed, for example, from Indium Tin Oxide (ITO) or Alumimum-doped Zinc oxide (AZO or ZnO:Al). The transparent conductive oxide Ohmic contact layer may have a thickness of about 50 Angstroms to about 2000 Angstroms, typically about 1000 Angstroms, for example.

Such a transparent conductive oxide ohmic contact layer may be used, for example, to make electrical contact to the n-type side of the diode junction in the LED without obstructing transmission of light out of the LED through the n-type surface on which the transparent conductive oxide layer is disposed.

Such a transparent conductive oxide ohmic contact layer may improve n-side current spreading.

Such a transparent conductive oxide layer may be used to interconnect the n-side contacts of adjacent AlInGaP LEDs or microLEDs in an array to form a shared n-side electrical contact. Optical cross talk between the adjacent LEDs, in which light emitted by one of the LEDs appears to originate from the other LED, may be reduced because the transparent conductive oxide layer is very thin compared to the thickness (e.g., 2 to 3 microns) of a shared n-type AlInGaP layer that might otherwise be required to form such a shared n-side electrical contact.

The inventors have found that if such a transparent conductive oxide ohmic contact layer is disposed on an n-type AlInGaP layer and a metal contact is disposed on the transparent conductive oxide layer opposite from the n-type AlInGaP layer, the reflectivity at the interface with the n-type AlInGaP layer is greater than it would be if the metal contact were disposed directly on the n-type AlInGaP layer. Hence the transparent conductive oxide ohmic contact layer may be used to improve a reflective mirror function of an n-side metal contact for directing light out of the LED.

More generally, such a transparent conductive oxide ohmic contact layer may be used to boost the optical output power and increase design flexibility for AlInGaP LEDs and microLEDs.

A light emitting diode incorporating such a transparent conductive oxide ohmic contact layer may comprise, for example, a stack of semiconductor layers comprising an n-type (AlₓₙGa₁₋ₓₙ)_{yn}In_{1-yn}P layer, a p-type (AlₓₚGa₁₋ₓₚ)_{yp}In_{1-yp}P layer, and an active region disposed between the n-type (AlₓₙGa₁₋ₓₙ)_{yn}In_{1-yn}P layer and the p-type (AlₓₚGa₁₋ₓₚ)_{yp}In_{1-yp}P layer. The active region typically comprises at least one (Al_{xqw}Ga_{1-xqw})_{yqw}In_{1-yqw}P quantum well layer. The light emitting diode also comprises a transparent conductive oxide contact layer disposed on and making Ohmic contact to at least a portion of a surface of the n-type (AlₓₙGa₁₋ₓₙ)_{yn}In_{1-yn}P layer opposite from the active region. The subscripts characterizing the compositions of these layers satisfy the following constraints: 0≤xn≤0.6; 0≤yn<1; 0≤xp≤1; 0≤yp<1; 0≤xqw≤1; and 0≤yqw<1.

As noted above, the transparent conductive oxide contact layer may be or comprise, for example, an Indium Tin Oxide layer. The transparent conductive oxide contact layer may, for example, have a thickness perpendicular to the n-type (AlₓₙGa₁₋ₓₙ)_{yn}In_{1-yn}P layer of about 50Angstroms to about 2000 Angstroms.

The light emitting diode may have a maximum dimension parallel to the layers in the stack of, for example, greater than about 50 microns, greater than or equal to about 100 microns, greater than or equal to about 200 microns, or greater than or equal to about 500 microns. Alternatively, the light emitting diode may be a microLED having a maximum dimension parallel to the layers in the stack of, for example, less than or equal to about 50 microns, less than or equal to about 30 microns, less than or equal to about 20 microns, less than or equal to about 10 microns, or less than or equal to about 1 micron.

A display device may comprise a plurality of such LEDs or microLEDs arranged as pixel red emitters, where a pixel in such a display typically includes in addition to the red emitter two or more other LEDs emitting other colors, for example blue and green.

In some variations, the transparent conductive oxide contact layer is disposed only on a central portion of the surface of the n-type (AlₓₙGa₁₋ₓₙ)_{yn}In_{1-yn}P layer. In such variations the light emitting diode may also comprise a transparent dielectric layer disposed on portions of the surface of the n-type (AlₓₙGa₁₋ₓₙ)_{yn}In_{1-yn}P layer surrounding the transparent conductive oxide contact layer, and a second transparent conductive oxide layer disposed on the transparent dielectric layer and making physical and electrical contact with the transparent conductive oxide Ohmic contact layer. Such a light emitting diode may, for example, be a microLED having a maximum dimension parallel to the layers in the stack of, for example, less than or equal to about 50 microns. The light emitting diode may comprise, for example, a metal contact disposed on a central portion of a surface of the p-type (AlₓₚGa₁₋ₓₚ)_{yp}In_{1-yp}P layer opposite from the active region, and a dielectric layer disposed on portions of the surface of the p-type (AlₓₚGa₁₋ₓₚ)_{yp}In₁. layer surrounding the metal contact. The light emitting diode may comprise, for example, a metal electrical contact disposed on or electrically connected to the second transparent conductive oxide layer in a location such that is does not obstruct transmission of light emitted from the active region through the n-type (AlₓₙGa₁₋ₓₙ)_{yn}In_{1-yn}P layer.

The dielectric layers in these devices and the devices described below may be or comprise, for example, nitride or oxide materials such as SiO₂, TiO₂, and SiNₓ. The composition and thickness of the dielectric layer(s) can be optimized based on wavelength and performance/reliability requirements. The p-metal and n-metal in these devices and the devices described below can be selected based on AlInGaP material and process compatibility.

An LED array (e.g., a microLED array) may comprise, for example, at least a first and a second LED as in the variation described above arranged adjacent to each other, and a third transparent conductive oxide layer making physical and electrical contact with the second transparent conductive oxide layer on the first light emitting diode and making physical and electrical contact with the second transparent conductive oxide layer on the second light emitting diode. The third transparent conductive oxide layer together with the transparent conductive oxide contact layer and the second transparent conductive oxide layer on the first light emitting diode and the transparent conductive oxide contact layer and the second transparent conductive oxide layer on the second light emitting diode form a shared transparent conductive oxide contact to the n-type (AlₓₙGa₁₋ₓₙ)_{yn}In_{1-yn}P layer of the first light emitting diode and the n-type (AlₓₙGa₁₋ₓₙ)_{yn}In_{1-yn}P layer of the second light emitting diode. The shared transparent conductive oxide contact may have a thickness perpendicular to the n-type (AlₓₙGa₁₋ₓₙ)_{yn}In_{1-yn}P layers of, for example, about 50 Angstroms to about 2000 Angstroms, typically 1000 Angstroms, in a region between the first light emitting diode and the second light emitting diode.

In some variations, an AlInGaP LED comprises a metal contact disposed on the transparent conductive oxide contact layer opposite from the surface of the n-type (AlₓₙGa₁₋ₓₙ)_{yn}In_{1-yn}P layer and opposite from the active region. The transparent conductive oxide contact layer and the metal contact disposed on it together form a reflective interface with the surface of the n-type (AlₓₙGa₁₋ₓₙ)_{yn}In_{1-yn}P layer.

The metal contact may leave a majority of the surface of the n-type (AlₓₙGa₁₋ₓₙ)_{yn}In_{1-yn}P layer opposite from the active region unobstructed for transmission of light emitted from the active region. In such variations the LED may comprise a mirror disposed on and occupying a majority of a surface of the p-type (AlₓₚGa₁₋ₓₚ)_{yp}In_{1-yp}P layer opposite from the active region, and a metal contact disposed on a portion of a surface of the p-type (AlₓₚGa₁₋ₓₚ)_{yp}In_{1-yp}P layer adjacent to the mirror. Such LEDs are configured for light output through the n-type (AlₓₙGa₁₋ₓₙ)_{yn}In_{1-yn}P layer.

Alternatively, the transparent conductive oxide contact layer, the metal contact, and the reflective interface extend across a majority of the n-type (AlₓₙGa₁₋ₓₙ)_{yn}In_{1-yn}P layer opposite from the active region. In such variations the LED may comprise a metal contact disposed on a portion of a surface of the p-type (AlₓₚGa₁₋ₓₚ)_{yp}In_{1-yp}P layer opposite from the active region, with the metal contact leaving a majority of the surface of the p-type (AlₓₚGa₁₋ₓₚ)_{yp}In_{1-yp}P layer unobstructed for transmission of light. Such LEDs are configured for light output through the p-type (AlₓₚGa₁₋ₓₚ)_{yp}In_{1-yp}P layer.

In some variations the transparent conductive oxide contact layer extends across the entire surface of the n-type (AlₓₙGa₁₋ₓₙ)_{yn}In_{1-yn}P layer opposite from the active region and the surface of the n-type (AlₓₙGa₁₋ₓₙ)_{yn}In_{1-yn}P layer is free of any metallization obstructing transmission of light emitted from the active region through the n-type (AlₓₙGa₁₋ₓₙ)_{yn}In_{1-yn}P layer. Such an LED may comprise, for example, a metal contact disposed on a portion of the transparent conductive oxide contact layer extending laterally beyond the n-type (AlₓₙGa₁₋ₓₙ)_{yn}In_{1-yn}P layer. Alternatively, the LED may be of a flip-chip design, and comprise a metal contact disposed on a surface of the n-type (AlₓₙGa₁₋ₓₙ)_{yn}In_{1-yn}P layer opposite from the surface on which the transparent conductive oxide contact layer is disposed, and a metal contact disposed on a surface of the p-type (AlₓₚGa₁₋ₓₚ)_{yp}In_{1-yp}P layer opposite from the active region. In such LEDs current injection to the n-side is not through the transparent conductive oxide layer, but the transparent conductive oxide contact layer may improve n-side current spreading.

The AlInGaP LEDs and microLEDs disclosed herein may be used for example in the various devices and applications listed above in the Background section.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example microLED.

FIGS. 2A and 2B show, respectively, cross-sectional and top schematic views of an array of microLEDs. FIG. 2C shows a schematic top view of a microLED wafer from which microLED arrays such as those illustrated in FIGS. 2A and 2B may be formed.

FIG. 3A shows a schematic top view of an electronics board on which an array of microLEDs may be mounted, and FIG. 3B similarly shows an array of microLEDs mounted on the electronic board of FIG. 3A.

FIG. 4A shows a schematic cross-sectional view of an array of microLEDs arranged with respect to waveguides or microlenses and a projection lens. FIG. 4B shows an arrangement similar to that of FIG. 4A, without the waveguides or microlenses.

FIG. 5 schematically illustrates an example display (e.g., AR/VR/MR) system that includes an array of microLEDs.

FIG. 6 shows a schematic cross-sectional view of an example vertical thin film microLED comprising a transparent conductive oxide layer making Ohmic contact to an n-type AlInGaP layer

FIG. 7 shows a schematic cross-sectional view of a portion of an example microLED array comprising two microLEDs as shown in FIG. 6.

FIG. 8 shows a schematic cross-sectional view of an example n-side up (light emission through then-side) vertical thin film light emitting diode comprising a transparent conductive oxide layer making Ohmic contact to an n-type AlInGaP layer.

FIG. 9 shows a schematic cross-sectional view of an example p-side up vertical thin film light emitting diode comprising a transparent conductive oxide layer making Ohmic contact to an n-type AlInGaP layer.

FIG. 10 shows a schematic cross-sectional view of another example n-side up (light emission through then-side) vertical thin film light emitting diode comprising a transparent conductive oxide layer making Ohmic contact to an n-type AlInGaP layer.

FIG. 11 shows a schematic cross-sectional view of an example AlInGaP flip chip light emitting diode comprising a transparent conductive oxide layer making Ohmic contact to an n-type AlInGaP layer.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual LED 100 comprising a light emitting semiconductor diode (LED) structure 102 disposed on a substrate 104. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

Although this specification focuses on direct emitting AlInGaP LEDs and microLEDs, more generally direct emitting and phosphor converted LEDs and microLEDs (both referred to herein as pcLEDs) may be formed in other material systems, such as for example AlInGaN. Generally, a pcLED comprises a phosphor material that absorbs light from the LED and in response emits longer wavelength light that forms all or part of the light output from the pcLED. Such pcLEDs may comprise ultraviolet or blue emitting AlInGaN LEDs in combination with a phosphor, for example. The AlInGaP LEDs and microLEDs disclosed in this specification may be used in combination with direct emitting LEDs or microLEDs formed in such other material systems and/or with pcLEDs. For example, red emitting AlInGaP microLEDs as disclosed in this specification may be used in combination with direct emitting AlInGaN microLEDs or phosphor converted microLEDs (pc-microLEDs) that emit blue or green light to form RGB pixels for displays.

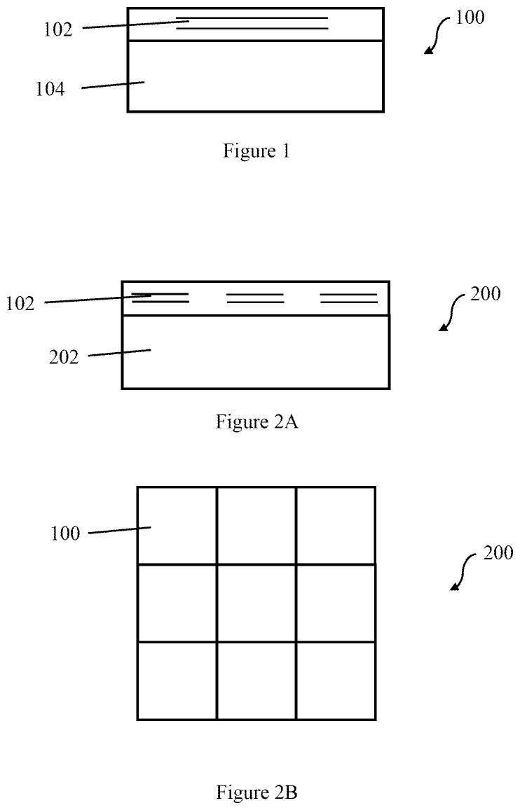

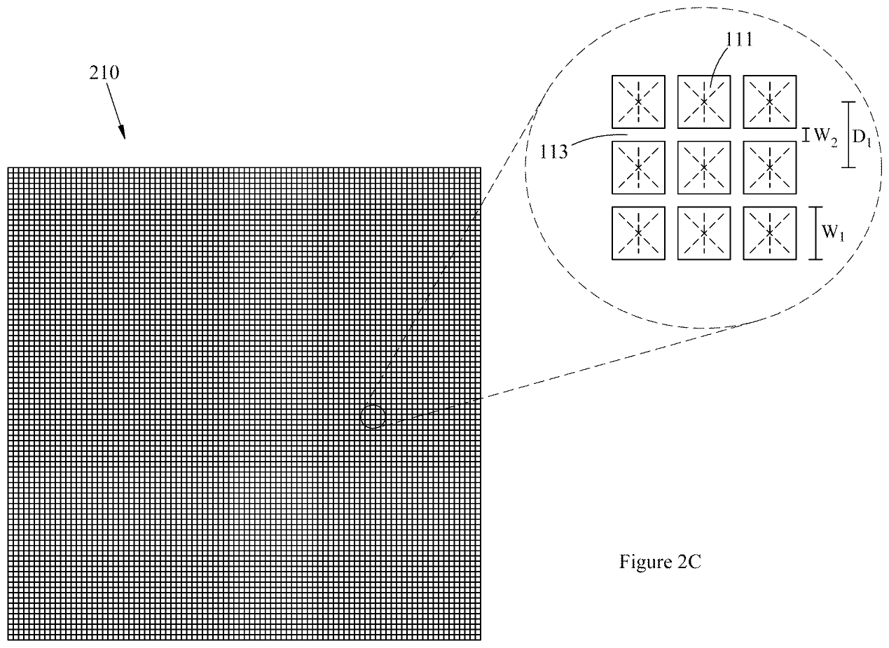

FIGS. 2A-2B show, respectively, cross-sectional and top views of an array 200 of LEDs 100 disposed on a substrate 202. Such an array may include any suitable number of LEDs arranged in any suitable manner. In the illustrated example the array is depicted as formed monolithically on a shared substrate, but alternatively an array of LEDs may be formed from separate individual LEDs. Substrate 202 may optionally comprise CMOS circuitry for driving the microLEDs and may be formed from any suitable materials.

Although FIGS. 2A-2B show a three-by-three array of nine LEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, less than or equal to 50 microns, less than or equal to 30 microns, less than or equal to 10 microns or less than or equal to 1 micron.

The LEDs in such an array may be spaced apart from each other by streets or lanes having a width in the plane of the array of, for example, hundreds of microns, less than or equal to 100 microns, less than or equal to 50 microns, less than or equal to 30 microns, less than or equal to 10 microns, or less than or equal to 5 microns. Although the illustrated examples show rectangular microLEDs arranged in a symmetric matrix, the microLEDs and the array may have any suitable shape or arrangement. Although the illustrated examples show an array in which all microLEDs are of the same size, microLEDs in an array may differ in size.

Further, as noted above such an array may include LEDs that are formed from different material systems and emit different colors of light and/or include pc-microLEDs.

FIG. 2C shows a schematic top view of a portion of a microLED wafer 210 (e.g., an AlInGaP LED wafer) from which LED arrays such as those illustrated in FIGS. 2A and 2B may be formed. FIG. 2C also shows an enlarged 3×3 portion of the wafer. In the example wafer individual LEDs 111 having side lengths (e.g., widths) of W₁ are arranged as a square matrix with neighboring LEDs having a center-to-center distances D₁ and separated by lanes 113 having a width W₂. W₁ may be, for example, less than or equal to 1 millimeter (mm), less than or equal to 500 microns, less than or equal to 100 microns, less than or equal to 50 microns, less than or equal to 30 microns, less than or equal to 10 microns, less than or equal to 5 microns, or less than or equal to 1 micron. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by separating wafer 210 into individual LEDs and arranging the LEDs on a substrate (e.g., in combination with LEDs or microLEDs formed in other material systems and/or pc LEDs or pc-microLEDs). Alternatively, an array may be formed from the entire wafer 210, or by dividing wafer 210 into smaller arrays of LEDs.

As noted above LEDs or pcLEDs having dimensions in the plane of the array (e.g., side lengths) of less than or equal to about 50 microns are typically referred to as microLEDs, and an array of such microLEDs may be referred to as a microLED array.

The individual LEDs or pcLEDs in an array may be individually operable (addressable) and/or may be operable as part of a group or subset of (e.g., adjacent) LEDs or pcLEDs in the array. A single individually operable LED or pcLED or a group of adjacent such LEDs and/or pcLEDs may correspond to a single pixel (picture element) in a display. For example, a group of three individually operable adjacent LEDs and/or pcLEDs comprising a red emitter, a blue emitter, and a green emitter may correspond to a single color-tunable pixel in a display.

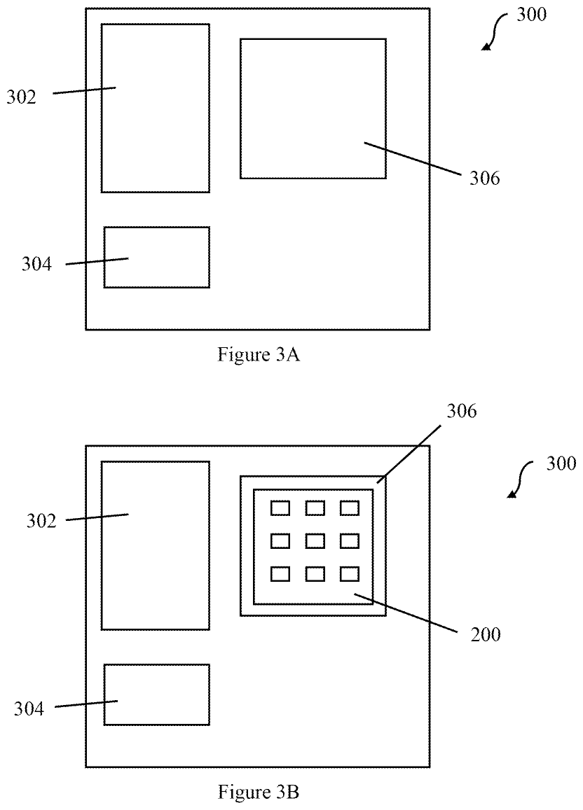

As shown in FIGS. 3A-3B, an LED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs and/or pcLEDs in the array. Sensor module 304 may receive signals from any suitable sensors, for example from temperature or light sensors. Alternatively, array 200 may be mounted on a separate board (not shown) from the power and control module and the sensor module.

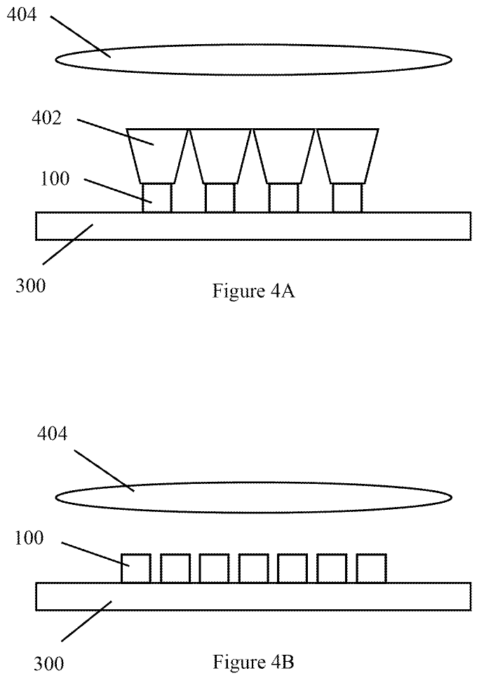

As shown in FIG. 4A, individual LEDs or pcLEDs may optionally incorporate or be arranged in combination with a lens (e.g., a microlens for microLEDs or pc-microLEDS) or other optical element located adjacent to or disposed on the LED or the phosphor layer of the pcLED. In addition, as shown in FIGS. 4A-4B an array 200 (for example, mounted on an electronics board 300) may be arranged in combination with a light collection optic or optical system (e.g., a projection lens 404). In FIG. 4A, light emitted by LEDs and/or pcLEDs 100 is collected by waveguides or lenses (e.g., microlenses) 402 and directed to projection lens 404. Projection lens 404 may be a Fresnel lens, for example. In FIG. 4B, light emitted by LEDs and/or pcLEDs 100 is collected directly by projection lens 404 without use of intervening optics. This arrangement may be particularly suitable when LEDs or pcLEDs can be spaced sufficiently close to each other. A microLED display application may use optical arrangements similar to those depicted in FIGS. 4A-4B, for example. Generally, any suitable arrangement of optical elements may be used in combination with the arrays described herein, depending on the desired application.

FIG. 5 schematically illustrates an example display (e.g., AR/VR/MR) system 500 that includes a microLED and/or pc-microLED array 510, display 520, a light emitting array controller 530, sensor system 540, and system controller 550. Control input is provided to the sensor system 540, while power and user data input is provided to the system controller 550. In some embodiments modules included in system 500 can be compactly arranged in a single structure, or one or more elements can be separately mounted and connected via wireless or wired communication. For example, the light emitting array 510, display 520, and sensor system 540 can be mounted on a headset or glasses, with the light emitting controller and/or system controller 550 separately mounted. System 500 can incorporate a wide range of optics in light emitting array 510 and/or display 520, for example to couple light emitted by light emitting array 510 into display 520.

Sensor system 540 can include, for example, external sensors such as cameras, depth sensors, or audio sensors that monitor the environment, and internal sensors such as accelerometers or two or three axis gyroscopes that monitor an AR/VR/MR headset position. In some embodiments, control input can include detected touch or taps, gestural input, or control based on headset or display position.

In response to data from sensor system 540, system controller 550 can send images or instructions to the light emitting array controller 530. Changes or modifications to the images or instructions can also be made by user data input, or automated data input as needed. User data input can include but is not limited to that provided by audio instructions, haptic feedback, eye or pupil positioning, or connected keyboard, mouse, or game controller.

As summarized above, this specification discloses AlInGaP LEDs and microLEDs comprising a transparent conductive oxide layer disposed on and making Ohmic contact to an n-type AlInGaP layer. Forming a transparent conductive oxide layer that makes Ohmic contact with an n-type AlInGaP layer is inherently difficult because of the electronic band structure and doping of the n-type AlInGaP layer. The inventors have found that such a transparent conductive oxide Ohmic contact layer may be formed on an n-type AlInGaP layer by suitable choice of the amount of Aluminum in the layer (which affects the band structure) and suitable choice of the n-type dopant density. Generally, the lower the Aluminum content the easier it is to make Ohmic contact between a transparent conductive oxide layer and an n-type AlInGaP layer. For an n-type layer having composition (AlₓₙGa₁₋ₓₙ)_{yn}In_{1-yn}P layer, Ohmic contact may be made for example, for 0≤xn≤0.6, depending in part on the dopant densities used. The n-type dopant may be, for example, Silicon. Ohmic contact may be made between the transparent conductive oxide layer and the n-type AlInGaP layer for Silicon dopant densities of, for example, 3×10¹⁷/(cm)³≤[Si]≤5×10¹⁸/(cm)³, depending in part on the Aluminum content in the layer.

Generally, the process for forming a transparent conductive oxide layer making Ohmic contact to an n-type AlInGaP layer comprises the following steps. First, an n-type AlInGaP layer having suitable Aluminum content and suitable n-type dopant density is formed. The Aluminum content is typically chosen to facilitate Ohmic contact and may also depend on the desired emission wavelength of the light emitting diode. Next, the surface on which the transparent conductive oxide layer is to be deposited is cleaned, for example with a wet etch or dry etch process. Next, the transparent conductive oxide layer (e.g., Indium Tin Oxide) is deposited on the surface of the n-type AlInGaP layer. This may be done, for example, using e-beam evaporation, RF sputtering, ion-beam sputtering, or atomic layer deposition (ALD) with or without plasma. Typically, the transparent conductive oxide layer, as deposited, does not make Ohmic contact with the n-type AlInGaP layer. Generally, an annealing process is required to achieve Ohmic contact. The temperature for the annealing process may be, for example, about 300° C. to about 475° C., depending on the thickness of the transparent conductive oxide layer, the Aluminum content of the AlInGaP layer, and the n-type dopant concentration in the AlInGaP layer. Typically, the Ohmic contact improves and the resistance of the Ohmic contact decreases as the annealing temperature is increased.

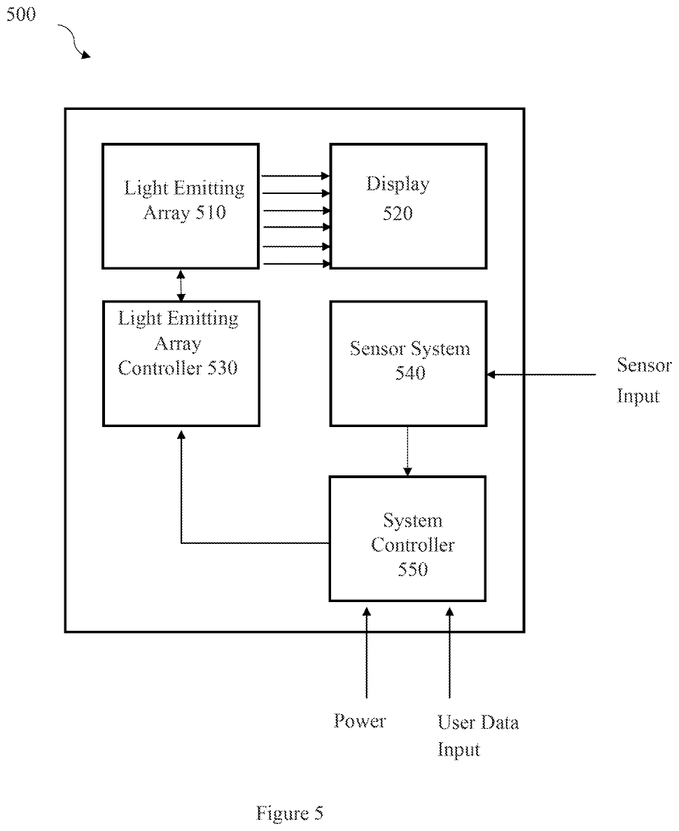

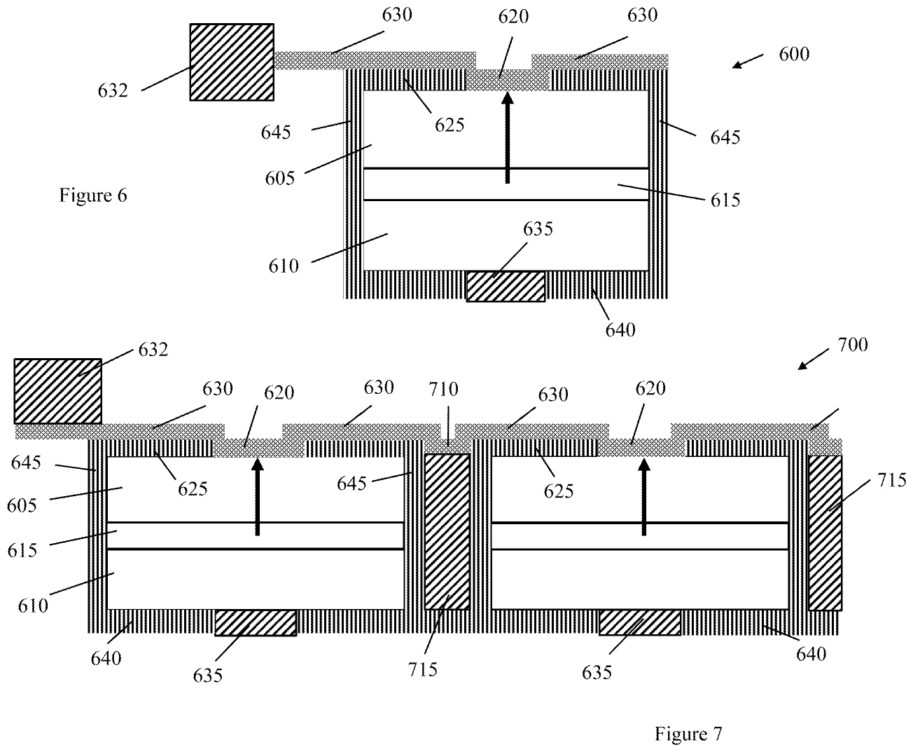

FIG. 6 to FIG. 11 described below show example AlInGaP LED and microLED devices incorporating a transparent conductive oxide layer making Ohmic contact to an n-type AlInGaP layer. These devices typically emit light having a peak wavelength of about 580 nm to about 660 nm, for example 630 nm or 650, depending primarily on the structure and composition of one or more quantum wells in their light emitting active regions. Constraints on the subscripts characterizing the compositions of the various materials in these devices are presented above in the summary section.

FIG. 6 shows a schematic cross-sectional view of an example vertical thin film microLED 600. MicroLED 600 comprises an n-type (AlₓₙGa₁₋ₓₙ)_{yn}In_{1-yn}P layer 605, a p-type (AlₓₚGa₁₋ₓₚ)_{yp}In_{1-yp}P layer 610, and an active region 615 disposed between the n-type 605 and the p-type layer 610. The active region typically comprises at least one (Al_{xqw}Ga_{1-xqw})_{yqw}In_{1-yqw}P quantum well layer (not shown). MicroLED 600 comprises a transparent conductive oxide Ohmic contact layer 620 disposed on a central portion of the surface of the n-type layer 605. A transparent dielectric layer 625 disposed on portions of the surface of the n-type layer surrounds the transparent conductive oxide Ohmic contact layer 620. A second transparent conductive oxide layer 630 is disposed on the transparent dielectric layer 625 and makes physical and electrical contact with the transparent conductive oxide Ohmic contact layer 620. Transparent conductive oxide layers 620 and 630 may be formed from the same transparent conductive oxide, for example, and may be formed as a single continuous layer with the reference numerals 620 and 630 designating different portions of the same layer.

A metal electrical contact 632 is disposed on or electrically connected to the second transparent conductive oxide layer 630 in a location such that it does not obstruct transmission of light emitted from the active region through the n-type layer. A metal electrical contact 635 is disposed on a central portion of a surface of p-type layer 610 opposite from the active region. A dielectric layer 640 is disposed on portions of the surface of the p-type layer surrounding metal contact 635, and further dielectric layers 640 may coat side walls of the device.

Upon application of a suitable forward voltage across contacts 632 and 635 the microLED emits light through the n-type layer, the transparent conductive oxide layers, and the transparent dielectric layer as shown by the central vertical arrow in the diagram. This arrangement allows for high light extraction efficiency from the microLED because there need not be any metal contacts obstructing transmission of light out of the n-type layer. This is particularly important for microLEDs, for which metal contacts to the n-type layer might obstruct a significant portion of the relatively small (e.g., 50 microns×50 microns) surface area of the n-type layer. MicroLED 600 may be used in direct view microLED displays, for example.

FIG. 7 shows a schematic cross-sectional view of a portion of a microLED array 700 comprising two microLEDs as shown in FIG. 6 arranged adjacent to each other. Array 700 also comprises a transparent conductive oxide layer 710 disposed between the two microLEDs and making physical and electrical contact with the transparent conductive oxide layers 630 on the two microLEDs. Transparent conductive oxide layers 710, 630, and 620 together form a shared transparent conductive oxide contact to the n-type layer of the two microLEDs.

Transparent conductive oxide layers 710, 630, and 620 may be formed from the same transparent conductive oxide, for example, and may be formed as a single continuous layer with the reference numerals 710, 620, and 630 designating different portions of the same layer.

As shown in FIG. 7, transparent conductive oxide 720 may be formed on and make electrical contact to n-side metal electrodes 715, which carry current to other microLEDs in the array positioned behind those shown in the figure.

The shared transparent conductive oxide n-side contact may have a thickness perpendicular to the n-type layers of, for example, about 50 Angstroms to about 2000 Angstroms in the region between the first light emitting diode and the second light emitting diode. This is sufficiently thin (e.g., significantly less than a wavelength of the light emitted by the microLEDs) that little or no light will leak through the shared transparent conductive oxide n-side contact from one microLED to an adjacent microLED. Hence this arrangement minimizes optical cross-talk between adjacent microLEDs.

MicroLED array 700 may be used in microLED displays, for example in Augmented Reality displays.

FIGS. 8-11 schematically illustrate LEDs having largest dimensions parallel to the layers in the stack of, for example, greater than or equal to about 100 microns, greater than or equal to about 200 microns, greater than or equal to about 500 microns, or greater than or equal to about 1 millimeter. Such LEDs may be used, for example, in traffic lights, automobile tail (e.g., brake) lights, and other illumination applications.

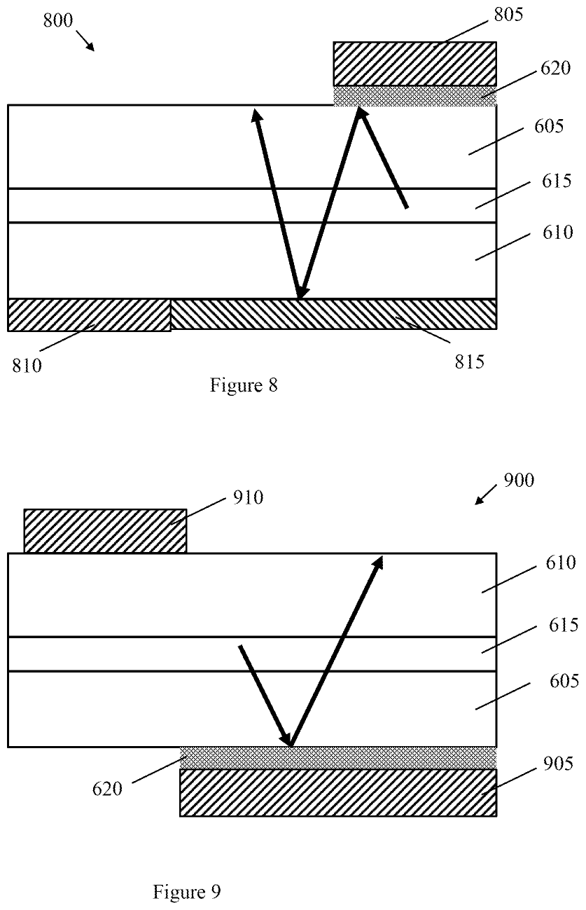

FIG. 8 shows a schematic cross-sectional view of an example n-side up (light emission through the n-side) vertical thin film light emitting diode 800. FIG. 9 shows a schematic cross-sectional view of an example p-side up (light emission through the p-side) vertical thin film light emitting diode 900. As in the light emitting diodes described above with respect to FIG. 6 and FIG. 7, light emitting diodes 800 and 900 comprise n-type AlInGaP layers 605, p-type AlInGaP layers 610, AlInGaP active regions 615, and transparent conductive oxide Ohmic contact layers 620 disposed on the n-type AlInGaP layers.

Example light emitting diode 800 comprises an n-side metal contact 805 disposed on transparent conductive oxide Ohmic contact layer 620. Example light emitting diode 900 similarly comprises an n-side metal contact 905 disposed on transparent conductive oxide Ohmic contact layer 620. As noted above, the inventors have found that a metal contact disposed on a transparent conductive oxide Ohmic contact layer (as in FIG. 8 and FIG. 9) provides better reflectivity at the n-type AlInGaP interface than does a metal contact disposed directly on the n-type AlInGaP layer. This is because the interface comprising the transparent conductive oxide Ohmic contact layer is smoother than an interface formed directly between the metal contact and the n-type AlInGaP layer. The interface comprising the transparent conductive oxide Ohmic contact layer is smoother because the transparent conductive oxide layer reduces interdiffusion between the metal contact and the n-type AlInGaP layer. Such interdiffusion would roughen the interface, promote scattering and absorption, and reduce specular reflection.

Example light emitting diode 800 comprises a p-side metal contact and a p-side mirror 815 occupying the majority of the p-side surface and forming a backside mirror for the device. N-side metal contact 805 leaves the majority of the n-type AlInGaP surface unobstructed for light transmission. Further, because of the high reflectivity at the n-type AlInGaP interface beneath the n-side metal contact, light incident on that interface may be reflected with high efficiency toward p-side mirror 815 and then reflected through the stack of layers and out of the device through the n-type AlInGaP layer (as shown by the arrows in the figure). This increases the efficiency of the device compared to an n-side up vertical thin film light emitting diode lacking the transparent conductive oxide Ohmic contact layer.

In example light emitting diode 900, transparent conductive oxide Ohmic contact layer 620 and n-side metal contact 905 extend across the majority of the n-type AlInGaP surface to form a high reflectance backside mirror. Light incident on the AlInGaP interface beneath the n-side metal contact may be reflected back through the stack of layers and out of the device through the p-type AlInGaP layer (as shown by the arrows in the figure). A p-side metal contact 910 leaves a majority of the p-side layer surface unobstructed for transmission of light out of the device.

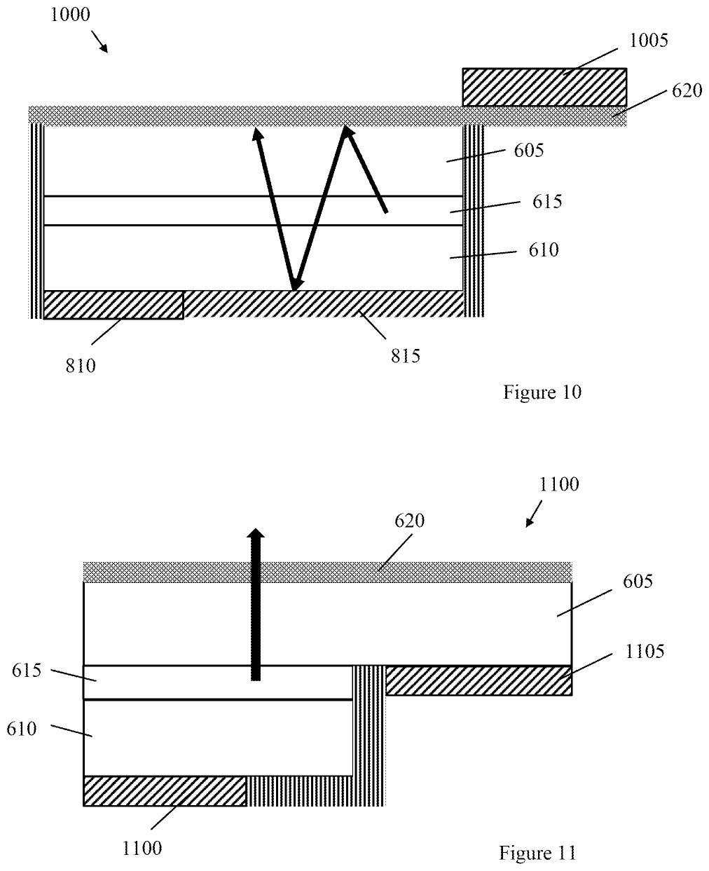

FIG. 10 shows a schematic cross-sectional view of another example n-side up (light emission through the n-side) vertical thin film light emitting diode 1000. In light emitting diode 1000 transparent conductive oxide Ohmic contact layer 620 extends across the entire surface of the n-type layer opposite from the active region and the surface of the n-type layer may be free of any metallization (e.g., fingers) obstructing transmission of light emitted from the active region through the n-type layer. Light emitting diode 1000 comprises an n-side metal contact 1005 disposed on a portion of the transparent conductive oxide contact layer extending laterally beyond the n-type AlInGaP layer. Light emitting diode 1000 is otherwise similar to light emitting diode 800 described above. Reducing or eliminating n-side metallization on the output surface of the n-type AlInGaP layer in this way improves light extraction from the device.

FIG. 11 shows a schematic cross-sectional view of an example AlInGaP flip chip light emitting diode 1100. As in the light emitting diodes described above, flip chip light emitting diode 1100 comprises n-type AlInGaP layer 605, p-type AlInGaP layer 610, AlInGaP active region 615, and a transparent conductive oxide Ohmic contact layer 620 disposed on a surface of the n-type AlInGaP layer. Light emitting diode 1100 also comprises a metal contact 1105 disposed on a surface of the n-type layer opposite from the surface on which the transparent conductive oxide layer is disposed, and a metal contact 1110 disposed on a surface of the p-type layer opposite from the active region. Current injection into the n-side of light emitting diode 1100 is not through the transparent conductive oxide layer, but the transparent conductive oxide contact layer may improve n-side current spreading because it provides a low resistance path for current to move laterally parallel to and then back into the n-type layer. As shown by the arrow in the figure, light emission from this device is through the n-type layer 605 and the transparent conductive oxide Ohmic contact layer. 620.

This disclosure is illustrative and not limiting. Further modifications will be apparent to one skilled in the art in light of this disclosure and are intended to fall within the scope of the appended claims.

What is claimed is:

1. A light emitting diode comprising:
a stack of semiconductor layers comprising
an n-type (AlₓₙGa₁₋ₓₙ)_{yn}In_{1-yn}P layer;
a p-type (AlₓₚGa₁₋ₓₚ)_{yp}In_{1-yp}P layer; and
an active region disposed between the n-type (AlₓₙGa₁₋ₓₙ)_{yn}In_{1-yn}P layer and the p-type (AlₓₚGa₁₋ₓₚ)_{yp}In_{1-yp}P layer and comprising at least one (Al_{xqw}Ga_{1-xqw})_{yqw}In_{1-yqw}P quantum well layer; and
a transparent conductive oxide contact layer disposed on and making Ohmic contact to at least a portion of a surface of the n-type (AlₓₙGa₁₋ₓₙ)_{yn}In_{1-yn}P layer opposite from the active region;
wherein
0≤xn≤0.6;
0≤yn<1;
0≤xp≤1;
0≤yp<1;
0≤xqw≤1; and
0≤yqw<1;

2. The light emitting diode of claim 1, wherein the transparent conductive oxide contact layer is or comprises an Indium Tin Oxide layer.

3. The light emitting diode of claim 1, wherein the transparent conductive oxide contact layer has a thickness perpendicular to the n-type (AlₓₙGa₁₋ₓₙ)_{yn}In_{1-yn}P layer of about 50 Angstroms to about 2000 Angstroms.

4. The light emitting diode of claim 1, wherein the transparent conductive oxide contact layer is disposed only on a central portion of the surface of the n-type (AlₓₙGa₁₋ₓₙ)_{yn}In_{1-yn}P layer, comprising:
a transparent dielectric layer disposed on portions of the surface of the n-type (AlₓₙGa₁₋ₓₙ)_{yn}In_{1-yn}P layer surrounding the transparent conductive oxide contact layer; and
a second transparent conductive oxide layer disposed on the transparent dielectric layer and making physical and electrical contact with the transparent conductive oxide contact layer.

5. The light emitting diode of claim 4, wherein the n-type (AlₓₙGa₁₋ₓₙ)_{yn}In_{1-yn}P layer has a maximum dimension parallel to the layer and opposite from the active region of less than or equal to about 50 microns.

6. The light emitting diode of claim 5, comprising:
a metal contact disposed on only a central portion of a surface of the p-type (AlₓₚGa₁₋ₓₚ)_{yp}In_{1-yp}P layer opposite from the active region; and
a dielectric layer disposed on portions of the surface of the p-type (AlₓₚGa₁₋ₓₚ)_{yp}In_{1-yp}P layer surrounding the metal contact.

7. The light emitting diode of claim 5, comprising a metal contact disposed on or electrically connected to the second transparent conductive oxide layer, the metal contact not obstructing transmission of light emitted from the active region through the (AlₓₙGa₁₋ₓₙ)_{yn}In_{1-yn}P layer.

8. A display device comprising a plurality of LEDs as in claim 5 configured and arranged as pixel red emitters.

9. A light emitting microLED array comprising:
at least a first and a second light emitting diode as in claim 5 arranged adjacent to each other; and
a third transparent conductive oxide layer making physical and electrical contact with the second transparent conductive oxide layer on the first light emitting diode and making physical and electrical contact with the second transparent conductive oxide layer on the second light emitting diode;
wherein the third transparent conductive oxide layer together with the transparent conductive oxide contact layer and the second transparent conductive oxide layer on the first light emitting diode and the transparent conductive oxide contact layer and the second transparent conductive oxide layer on the second light emitting diode form a shared transparent conductive oxide contact to the n-type (AlₓₙGa₁₋ₓₙ)_{yn}In_{1-yn}P layer of the first light emitting diode and the n-type (AlₓₙGa₁₋ₓₙ)_{yn}In_{1-yn}P layer of the second light emitting diode.

10. The light emitting microLED array of claim 9, wherein the shared transparent conductive oxide contact has a thickness perpendicular to the n-type (AlₓₙGa₁₋ₓₙ)_{yn}In_{1-yn}P layers of about 50 Angstroms to about 2000 Angstroms in a region between the first light emitting diode and the second light emitting diode.

11. The light emitting microLED array of claim 9, wherein the at least first and second light emitting diodes each comprise:
a metal contact disposed on a central portion of a surface of the p-type (AlₓₚGa₁₋ₓₚ)_{yp}In_{1-yp}P layer opposite from the active region; and
a dielectric layer disposed on portions of the surface of the p-type (AlₓₚGa₁₋ₓₚ)_{yp}In_{1-yp}P layer surrounding the metal contact.

12. The light emitting microLED array of claim 9, comprising a metal contact disposed on or electrically connected to the shared transparent conductive oxide contact, the metal contact not obstructing transmission of light emitted from the active region through the (AlₓₙGa₁₋ₓₙ)_{yn}In_{1-yn}P layer of either the first or the second light emitting diodes.

13. The light emitting diode of claim 1, comprising a metal contact disposed on the transparent conductive oxide contact layer opposite from the surface of the n-type (AlₓₙGa₁₋ₓₙ)_{yn}In_{1-yn}P layer and opposite from the active region, the transparent conductive oxide contact layer and the metal contact disposed on it together forming a reflective interface with the surface of the n-type (AlₓₙGa₁₋ₓₙ)_{yn}In_{1-yn}P layer.

14. The light emitting diode of claim 13, wherein the metal contact leaves a majority of the surface of the n-type (AlₓₙGa₁₋ₓₙ)_{yn}In_{1-yn}P layer opposite from the active region unobstructed for transmission of light emitted from the active region.

15. The light emitting diode of claim 14, comprising:
a mirror disposed on and occupying a majority of a surface of the p-type (AlₓₚGa₁₋ₓₚ)_{yp}In_{1-yp}P layer opposite from the active region; and
a metal contact disposed on a portion of a surface of the p-type (AlₓₚGa₁₋ₓₚ)_{yp}In_{1-yp}P layer adjacent to the mirror.

16. The light emitting diode of claim 1, wherein the transparent conductive oxide contact layer, the metal contact, and the reflective interface extend across a majority of the n-type (AlₓₙGa₁₋ₓₙ)_{yn}In_{1-yn}P layer opposite from the active region.

17. The light emitting diode of claim 16, a metal contact disposed on a portion of a surface of the p-type (AlₓₚGa₁₋ₓₚ)_{yp}In_{1-yp}P layer opposite from the active region, the metal contact leaving a majority of the surface of the p-type (AlₓₚGa₁₋ₓₚ)_{yp}In_{1-yp}P layer unobstructed for transmission of light.

18. The light emitting diode of claim 1, wherein the transparent conductive oxide contact layer extends across the entire surface of the n-type (AlₓₙGa₁₋ₓₙ)_{yn}In_{1-yn}P layer opposite from the active region and is free of any metallization obstructing transmission of light emitted from the active region through the n-type (AlₓₙGa₁₋ₓₙ)_{yn}In_{1-yn}P layer.

19. The light emitting diode of claim 18, comprising a metal contact disposed on a portion of the transparent conductive oxide contact layer extending laterally beyond the n-type (AlₓₙGa₁₋ₓₙ)_{yn}In_{1-yn}P layer.

20. The light emitting diode of claim 18, comprising:
a metal contact disposed on a surface of the n-type (AlₓₙGa₁₋ₓₙ)_{yn}In_{1-yn}P layer opposite from the transparent conductive oxide contact layer; and
a metal contact disposed on a surface of the p-type (AlₓₚGa₁₋ₓₚ)_{yp}In_{1-yp}P layer opposite from the active region.
